(19) United States
(12) Patent Application Publication
(10) Pub. No.: US 2015/0362536 A1
(43) Pub. Date: Dec. 17, 2015

(54) HIGH-VOLTAGE DIRECT CURRENT BROAD FREQUENCY-DOMAIN CORONA CURRENT MEASUREMENT SYSTEM

(71) Applicants: Haiwen Yuan, Beijing (CN); STATE GRID CORPORATION OF CHINA, Beijing (CN); CHINA ELECTRIC POWER RESEARCH INSTITUTE, Beijing (CN)

(72) Inventors: Jiayu LU, Beijing (CN); Haiwen YUAN, Beijing (CN); Yuanqing LIU, Beijing (CN); Jianxun LV, Beijing (CN); Jiangang WANG, Beijing (CN); Wenyue XIA, Beijing (CN); Lianlian LI, Beijing (CN); Jian GUO, Beijing (CN); Yong JU, Beijing (CN)

(21) Appl. No.: 14/420,617

(22) PCT Filed: Aug. 7, 2013
(86) PCT No.: PCT/CN2013/080946

§ 371 Date: Aug. 20, 2015

(30) Foreign Application Priority Data
Aug. 7, 2012 (CN) 201210279738.7
Jan. 15, 2013 (CN) 201310013394.X

(51) Int. Cl. G01R 19/25; G01R 15/22; G01R 19/00

(52) U.S. Cl. CPC G01R 19/2513; G01R 19/0053; G01R 15/22

(57) ABSTRACT

The present invention provides a kind of high voltage direct current broadband domain corona current measurement system, including the sampling resistance sensor, the UHV local end measurement unit, the optical fiber transmission unit, the safe location measurement unit and the upper monitor; The sampling resistance sensor samples the corona current signal of the HVDC line, and converts the corona current signal to the voltage signal, the UHV local end measurement unit collects the voltage signal, and obtains the optical signal by photoelectric conversion, the optical signal transforms to the safe location measurement unit by the optical fiber transmission unit, the safe location measurement unit converts the optical signal to the voltage signal, the host computer performs processing, storing and displaying with the voltage signal. The present invention has a wide range of measuring frequency, strong ability of anti-electromagnetic interference and other advantages, also can running in long-term stable status under the condition of the UHV DC and all kinds of bad natures, this provides effective technological means for further research on the character of the UHVDC corona.

### FIELD OF THE INVENTION

The invention relates to a kind of technology solution in the high voltage testing equipment and measurement technology filed, more particularly, to a kind of high voltage direct current broadband domain corona current measurement system.

### BACKGROUND OF THE INVENTION

To implement the national energy policy, ensure that the power industry has a comprehensive, balanced and sustainable healthy development, the State Grid proposes a significant strategic move on accelerating the pace of development of the AD-DC UHV grid according to our national conditions. The UHV transmission is developed on the basis of extra-high voltage power transmission, it can realize long-distance and large capacity power transmission is suitable for regional power grid interconnection. Different form UHV AC transmission, UHV AC transmission lines have a lower cost and less power loss, is more suitable for long-distance and large capacity power transmission.

Due to the high voltage level, the UHV transmission conductor will be inevitable resulting in the corona phenomenon. The corona phenomenon of the UHV transmission lines include the corona loss, the field effect, the radio jamming, the audible noise and the space ion flow, etc. As the transmission voltage grade increasing, making a lot of countries draw a higher demand on anticorona, recently, to improve the capacity and distance of power transmission, our country has completed XIANGJIABA to SHANGHAI ±800 kV UHV DC transmission-n project, at the same time the State Grid has already launched previous research of the ±1100 kV HVDC transmission technology. As the HVDC transmission lines in our country will go pass different geographies and environments, with the increasing of the voltage grade, the corona effect will be more prominent. While the atmospheric environment quality of developed countries and our country vary widely, in the according filed of the UHV DC lines corona effect, these countries' experimental data and design methods are difficult to directly use for our country. Therefore it is necessary for a further research of the DC lines corona effect.

The above issues related to the electromagnetic environment most source lies in the corona discharge, and the space radiation electromagnetic field generated by the corona current is the radio interference; High-speed movement of ions produced by corona results air compression generates audible noise, the DC line corona generates the space charge , further generates the space electric field. So that we must focus o-n researching the corona current which discovering the essential character of the electromagnetic environment parameters and the corona discharge. The corona discharge belongs random pulse discharge, has a wide spectrum in the engineering field, for radio interference and other electromagnetic environment parameters, the measure to more than 30 MHZ will be usually taken .From a research standpoint, it should be considered more wide domain. To this end, it is necessary to have an all-weather test method of the corona current broadband do-main, it is also necessary to provides necessary conditions for researching the corona current character under the erect of the UHV transmission lines, hybrid AC/DC transmission lines in different altitude and climatope.

The corona loss and the environmental effect caused by corona are the two key problem need to solved in the DC power transmission project, while corona current is the physic-al quantity directly related to the corona loss and the environmental effect, meanwhile it is also the most direct physical quantity related to the corona discharge situation of the token lines it can provide the reference for the wire configuration of the UHV transmission lines by studying the corona current. The measurement of the previous power system only pays attention to studying the corona loss, and the traditional measuring sampling frequency is low (usually under 2 MHZ), measure performance cannot satisfy the research demand of the UHV transmission line audible noise, the radio jamming an-d the DC synthesis as the corona current research need to b-e promoted, China Electric Power Research Institute has successfully created the sampling resistance sensor with 30 MHz band response. Southern Power Grid Technology Research Center and Tsinghua University have already developed the 50 MHz corona current measurement system, but those existing technology cannot meet the research demand of the UHV d-c corona character, it needs to further develop higher sampling frequency measurement system.

### SUMMARY OF THE INVENTION

In order to overcome the shortage of the existing technology, the present invention provides a kind of high voltage direct current broadband domain corona current measurement system, has a wide range of measuring frequency, strong ability of anti-electromagnetic interference and other advantages, also can running in long-term stable status under the condition of the UHV DC and all kinds of bad natures, this provides effective technological means for further research the character of the UHV DC corona.

To achieve the above objects, the present invention provides the following technical solutions:

A kind of high voltage direct current broadband domain corona current measurement system is provided by the present invention, said system includes the sampling resistance sensor, the UHV local end measurement unit, the optical fiber transmission unit, the safe location measurement unit and upper monitor; Said sampling resistance sensor and the UHV local end measurement unit both set in the integrated UHV local unit, said sampling resistance sensor samples the corona current signal of the HVDC line, and converts said corona current signal to the voltage signal, said UHV local end measurement unit collects said voltage signal, and gets the optical signal by photoelectric conversion, the said optical signal transforms to the said safe location measurement unit by the said optical fiber transmission unit, said upper monitor performs processing voltage signal, storage it and display it.

Said integrated UHV local unit includes the grading ring A, the sampling resistance sensor, the optical fiber waterproof connector, the UHV local end measurement unit and the shielding ring; Both sides of the integrated UHV local unit are respectively provided with the sampling resistance sensor and the UHV local end measurement unit, the outsides of the said sampling resistance sensor and the UHV local end measurement unit both provided with the shielding ring, the junction between said UHV local end measurement unit and its outside shielding ring has setting an optical fiber waterproof connector for leading the optical signal.

Said sampling resistance sensor includes shielding case, the epoxy resin insulating flange, the PE insulating framework, the compartments body and the sampling resistance; the said sampling resistances have the same resistance value, it is circumferentially arranged and is in the parallel form; locating in the internal of the compartments body, the said compartments body uses the PE insulating framework for being mechanical support bracket, the outside of the PE insulating framework provides the shielding case, the two ends of the said sampling resistance sensor links to the tubular bus-bar respectively by the said Epoxy resin insulating flange and the UHV local end measurement unit.

Said UHV local end measurement unit includes the high speed broadband domain data acquisition unit, USB port, the photoelectric conversion unit A, the serial port, the energy comprehensive management unit and the independent power supply unit; Said high speed broadband domain data acquisition unit connects with said sampling resistance sensor, collects said voltage signals, said voltage signal inputs said photoelectric conversion unit A through said USB port, after conversion the said optical signal is getting; Said Energy comprehensive management unit links to the photoelectric conversion unit A via serial port ; Said independent power supply unit supplies power for the high speed broadband domain data acquisition unit, the energy comprehensive management unit and the photoelectric conversion unit A.

Said independent power supply unit includes storage battery, said storage battery includes battery protect board, said battery protect board uses LFP materials.

Said storage battery includes optical fiber charging unit, uses the optical fiber for optical signal charging said storage battery.

Said High speed broadband domain data acquisition unit includes the AD convert unit, the FPGA unit, the ARM control unit, the buffer cell and the network transmission unit; Said FPGA unit uses the sampling clock to control said AD convert unit converting the corona current signal collected by the sampling resistance sensor into digital signal, and command the buffer cell A to cache the digital signal, said ARM control unit commands the FPGA unit and buffer cell B for transfer the digital signal, said network transmission unit transfers the digital signal to the said photoelectric conversion unit A by the USB port.

Said energy comprehensive management unit includes the power input interface, the power conversion unit, the power supply control circuit, the central control unit, the protection circuit, the power output interface A and the power output interface B; Said power conversion unit link to the said independent power supply unit via the said power input interface, supplying power for the said central control unit and the power supply control circuit is the one hand, on the other hand is controlling the power output interface A and the power output interface B outputting different voltage respectively, the said central control unit controls the said protection circuit and the power supply control circuit, realize power output controlling through the circuit on-off of said power supply control circuit, said protection circuit includes the gas discharge tube and the corresponding parallel TVS, to make sure the said energy comprehensive management unit cannot be surged by the instantaneous high pressure.

Said optical fiber transmission unit includes the optical fiber and the optical fiber insulator; The said optical fiber uses the outdoor multimode optical cable, said optical fiber insulator transfers said optical signal form the UHV local end measurement unit to said safe location measurement unit.

Said safe location measurement unit includes the photoelectric conversion unit B, the USB port, the serial port and the power subsystem; Said USB port and serial port link to the photoelectric conversion unit respectively, said power subsystem supplies power for the photoelectric conversion unit B.

Said upper monitor connects to the said safe location measurement unit by the USB port and the serial port, it receives, stores and processes said voltage signal, further get the corona current signal.

The sampling Rate of the said corona current signal is 1 kHz-1 GHz, its sampling depth is 1 kB˜18 128 MB.

Compared with the prior art, the invention has following advantages:
1. The sampling resistance sensor uses the sample resistance circular parallel form ,has minimum distortion and a wide range of measuring frequency which could reach 500 MHz, and will not generate the corona discharge under the UHV environment; This spread pattern of the resistance sensor can be more effective to reduce the inductance and capacitance distributing parameters of the sampling resistance, greatly improve the frequency response parameters;
2. Using the high speed broadband domain data acquisition unit have a high sampling rate, large storage depth and can better collect corona current signal;
3. Installing the sampling resistance sensor and the UHV local end measurement unit in the integrated UHV local unit uniformly, this utmost protects the sampling, collecting and processing of the corona current signal form the influence of the UHV electromagnetic environment outside, has a very good electromagnetic shielding effect;
4. Using digital optical fiber transmission unit has a large bandwidth, less loss, strong anti-interference ability and long effective distance, it satisfies the need of the remote measurement;
5. The optical fiber insulator isolates the high and low voltage effectively, protects the data transmission from the influence of the UHV electromagnetic special environment, ensures the corona current data reliable high-speed transmission ;
6. The broadband domain corona current measurement system present by the present invention could be running in long-term stable status under the condition of the UHV DC and all kinds of bad natures.

### BRIEF DESCRIPTION OF THE DRAWINGS

FIG. 1 is the Structure Diagram of the high voltage direct current broadband domain corona current measurement system;

FIG. 2 is the structure schematic diagram of the integrated UHV local unit in the high voltage direct current broadband domain corona current measurement system;

FIG. 3 is the schematic diagram of the optical fiber insulator in the high voltage direct current broadband domain corona current measurement system;

FIG. 4 is the Composition diagram of the High speed broadband domain data acquisition unit in the high voltage direct current broadband domain corona current measurement system;

FIG. 5 is the schematic diagram of the energy comprehensive management unit in the high voltage direct current broadband domain corona current measurement system;

FIG. 6 is the flow diagram of the receiving, storing and processing the signal by the upper monitor in the high voltage direct current broadband domain corona current measurement system;

FIG. 7 is the schematic diagram of the Corona current measurement results in the embodiment.

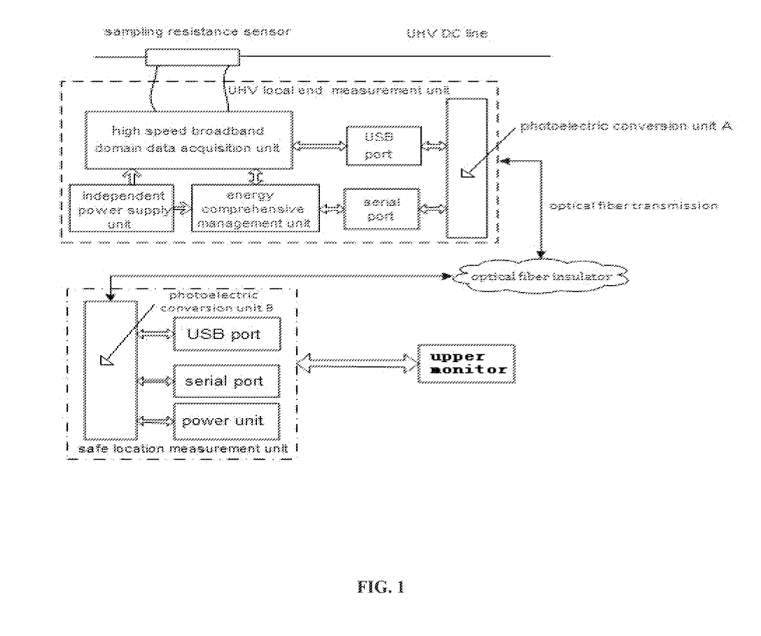

As shown in FIGS. 1-7: 1. Grading Ring A, 2. Shielding Case, 3. Epoxy Resin Insulating Flange, 4. PE Insulating Framework, 5. Compartments Body, 7. Storage Battery, 8. Optical Fiber Waterproof Connector, 9. UHV Local End Measurement Unit, 10. Shielding Ring, 11. Sampling Resistance, 12. Low-Voltage Terminal Link Fitting, 13. Low Voltage Measurement End Optical Fiber Connecting Box, 14. Optical Fiber Insulator Extend Fitting, 15. High Voltage Measurement End Optical Fiber Connecting Box, 16. Optical Fiber Insulator Fixed Expansion Spring, 17. Interface Connected Optical Fiber Insulator and Outdoor Fiber Optic Interface, 18. Interface Connected Optical Fiber Insulator and Optical Fiber of the Measurement System, 19, Grading Ring B, 20, Insulator.

### DETAILED DESCRIPTION OF EMBODIMENTS

The detail of the embodiments is described as below incorporated with the figures by way of cross-reference for the present invention.

As shown in FIG. 1, a kind of high voltage direct current broadband domain corona current measurement system, is characterized that, said system includes the sampling resistance sensor, the UHV local end measurement unit, the optical fiber transmission unit, the safe location measurement unit and upper monitor; Said sampling resistance sensor and UHV local end measurement unit both set in the integrated UHV local unit, said sampling resistance sensor samples the corona current signal of the HVDC line, and converts said corona current signal to the voltage signal, said UHV local end measurement unit collects said voltage signal, and gets the optical signal by Photoelectric conversion, Said optical signal transforms to the said safe location measurement unit by said optical fiber transmission unit, said upper monitor performs processing the voltage signal, storage it and display it.

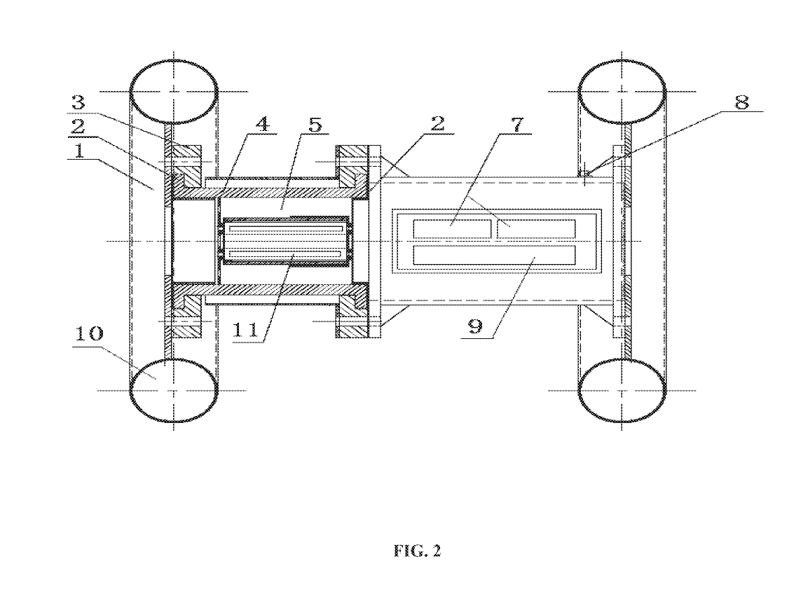

As shown in FIG. 2, said integrated UHV local unit includes the grading ring A, the sampling resistance sensor, the optical fiber waterproof connector 8, the UHV local end measurement unit 9, and the shielding ring 10; Both sides of the integrated UHV local unit are respectively provided with the sampling resistance sensor and the UHV local end measurement unit, the outsides of the said sampling resistance sensor and UHV local end measurement unit both provided with the shielding ring, using the four core optical fiber waterproof plug for connecting to the insulator, is the coffret of the optical signal. Grading ring A uses for reducing the surface electric field strength of the integrated UHV local unit to prevent surface discharge.

Said sampling resistance sensor includes shielding case 2, epoxy resin insulating flange 3, PE insulating framework 4, the compartments body 5 and four sampling resistances 11 with same resistance value; Said sampling resistance 11 uses zinc oxide ceramic tube non-inductive resistor, the four sampling resistances 11 are circumferentially arranged and use the parallel form; Locating in the internal of the compartments body 5, said compartments body 5 uses the PE insulating framework 4 for being mechanical support bracket, the outside of the PE insulating framework 4 provides the shielding case 2, the two ends of said sampling resistance sensor links to the tubular bus-bar respectively by said epoxy resin insulating flange 3 and UHV local end measurement unit 9. The hielding case 2 and shielding ring 10 use for shielding, better protect the Sampling resistor sensor form the influence of UHV DC magnetic field. The epoxy resin insulating flange 3, PE insulating framework 4, play the role of fixed and support. The strength of materials is very high, can adapt to the actual installation intensity.

Said UHV local end measurement unit 9 includes the high speed broadband domain data acquisition unit, the photoelectric conversion unit A, the serial port, the energy comprehensive management unit and the independent power supply unit; Said high speed broadband domain data acquisition unit connects with said sampling resistance sensor, collects said voltage signals, said voltage signal inputs said photoelectric conversion unit A through said USB port, after conversion gets said optical signal; Said energy comprehensive management unit links to the photoelectric conversion unit A via serial port; Said independent power supply unit supplies power for the High speed broadband domain data acquisition unit, the energy comprehensive management unit and the Photoelectric conversion unit A.

Said independent power supply unit includes storage battery 7. Said storage battery includes battery protect board, said battery protect board uses LFP materials. Its nominal capacity is 40 Ah.

Said storage battery 7 includes optical fiber charging unit, uses the optical fiber for optical signal charging said storage battery 7.

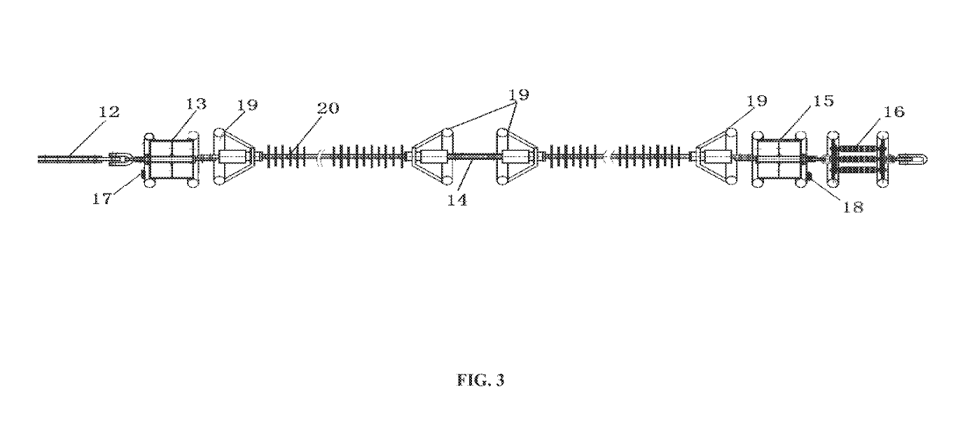

As shown in FIG. 3, said optical fiber transmission unit includes the optical fiber and the optical fiber insulator. Said optical fiber uses the outdoor multimode optical cable, said optical fiber insulator transfers said optical signal from the UHV local end measurement unit to said safe location measurement unit.

The optical fiber insulator includes low-voltage terminal link fitting 12, low voltage measurement end optical fiber connecting box 13, optical fiber insulator extend fitting 14, high voltage measurement end optical fiber connecting box 15, optical fiber insulator fixed expansion spring 16, interface connected optical fiber insulator and outdoor fiber optic interface 17, interface connected optical fiber insulator and optical fiber of the measurement system 18, grading ring B19 and insulator 20. Wherein low-voltage terminal link fitting 12 connects to the fixed point of low potential side, low voltage measurement end optical fiber connecting box 13, high voltage measurement end optical fiber connecting box 15 use for the delivery of outdoor optical fiber and optical fiber insulator, interface connected optical fiber insulator and outdoor fiber optic interface 17, interface connected optical fiber insulator and optical fiber of the measurement system 18 are the interface connected optical fiber insulator and outdoor fiber optic interface and the integrated UHV local unit, optical fiber insulator fixed expansion spring 16 uses for providing the optical fiber insulator a certain installation allowance and small scope activity ability, grading ring 19 uses to prevents surface discharge, insulator 20 uses for insulation between lines in the high side and the testing tower install hanging point.

Said safe location measurement unit includes the photoelectric conversion unit B, the USB port, the serial port and the power subsystem; The said USB port and serial port link to the photoelectric conversion unit respectively, said power subsystem supplies power for the photoelectric conversion unit B.

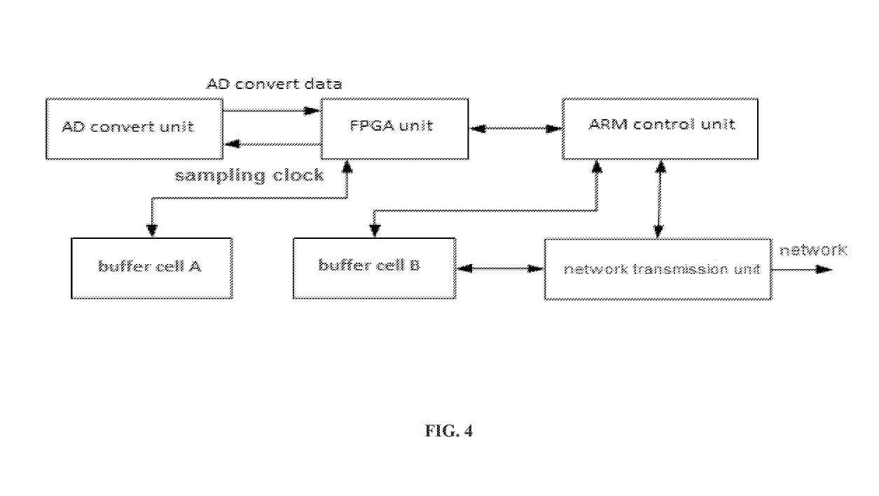

As shown in FIG. 4, said high speed broadband domain data acquisition unit includes the AD convert unit, the FPGA unit, the ARM control unit, the buffer cell and the network transmission unit; Said FPGA unit uses the sampling clock to control said AD convert unit converting the corona current signal collected by the Sampling resistance sensor into digital signal, and command the buffer cell A to cache the digital signal, said ARM control unit commands the FPGA unit and buffer cell B for transfer the digital signal, said network transmission unit transfers the digital signal to the said photoelectric conversion unit A by the USB port.

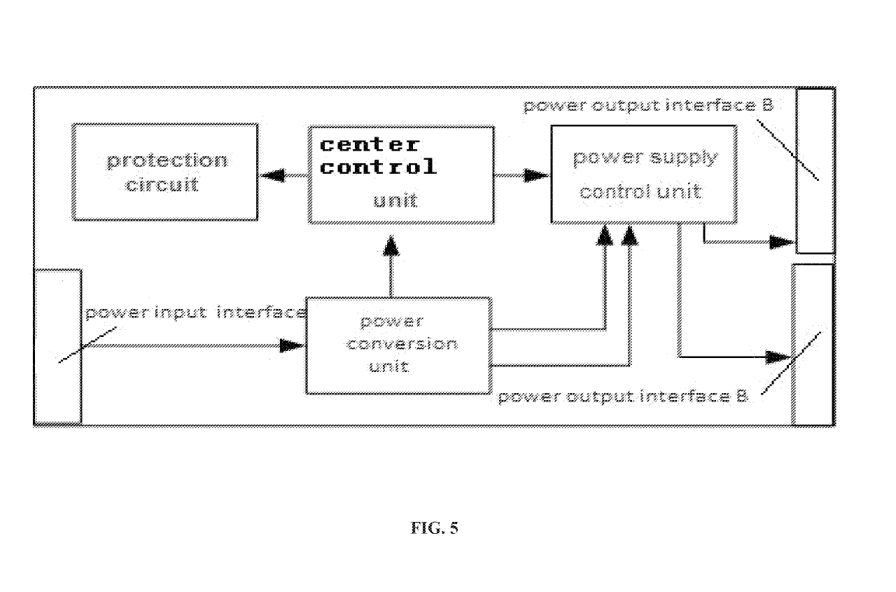

As shown in FIG. 5, said energy comprehensive management unit includes the power input interface, the power conversion unit, the power supply control circuit, the central control unit, the protection circuit, the power output interface A and the power output interface B; Said power conversion unit link to the said independent power supply unit via said power input interface, supplying power for said central processing unit and the power supply control circuit is the one hand to provide the center processing unit and power supply control circuit with electricity, on the other hand is controlling the power output interface A and the power output interface B outputting different voltage respectively, said central processing unit controls said protection circuit and the power supply control circuit, to realize power output controlling through the circuit on-off of said power supply control circuit. Said protection circuit includes the gas discharge tube and the corresponding TVS, to make sure that said energy comprehensive management unit cannot be surged by the instantaneous high pressure.

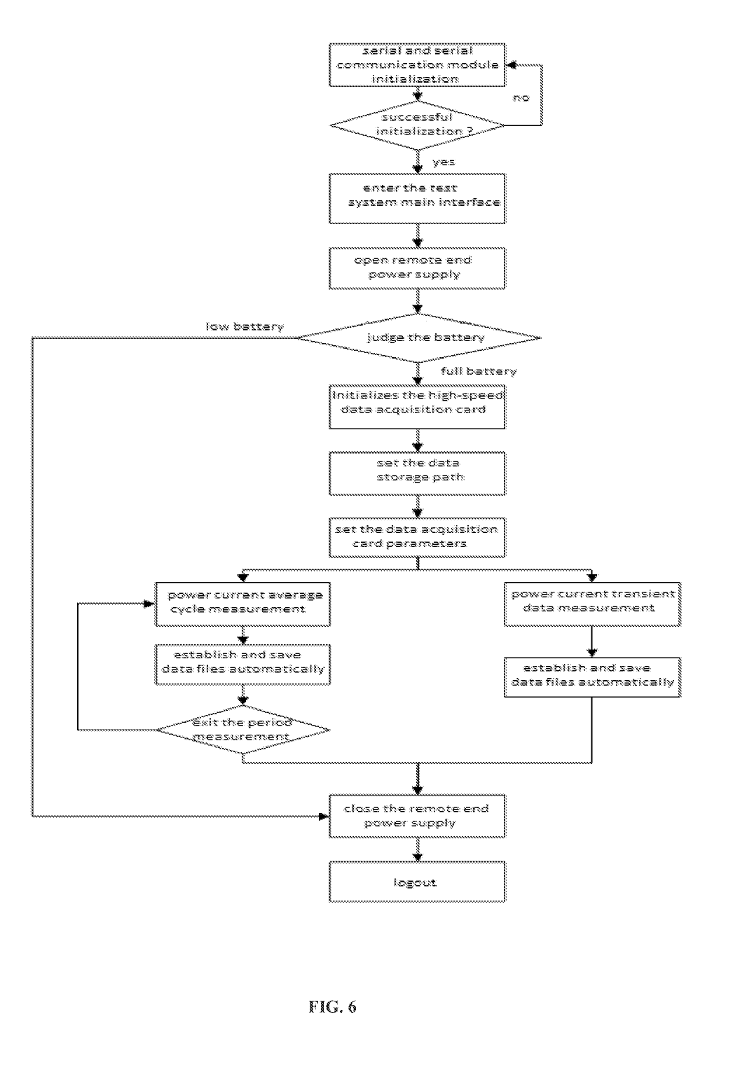

As shown in FIG. 6, said upper monitor connects to say safe location measurement unit by the USB port and the serial port, it receives, stores and processes said voltage signal, further get the corona current signal. And also need to control the energy comprehensive management module to achieve the result of power reduction.

The sampling rate of the said corona current signal is 1 kHz˜1 GHz, its sampling depth is 1 kB˜128 MB.

The system has been installed in UHV DC test base of State Grid and has been put into use, has made a lot of corona current measurements research work. The test base has a total length of 1084 meters of test segment, can be used to test double-circuit line on the same tower, the maximum voltage level of the double circuit DC could reach ±1200 kV. Its UHV bipolar dc generator supply DC power for the UHV DC test base, the maximum output voltage could reach ±1200 kV, output current is 0.5 A.

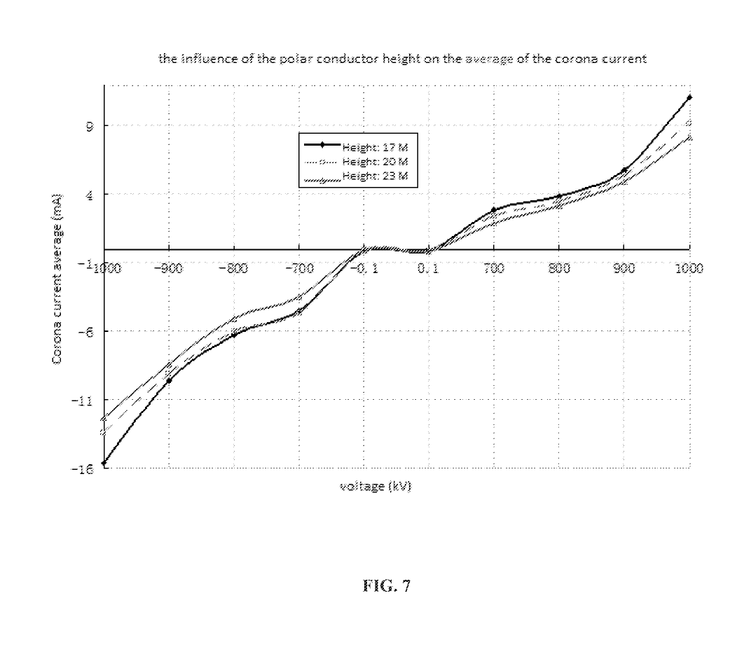

As shown in FIG. 7, the influence rule of different height of polar conductor on the result of the corona current measurements is obtained.

At last, in this description of the embodiment, we have detail describe the present invention according to a particular example. The detail embodiment is one example of the invention but not the only one, so the person in this field must be understand that all the alternatives and other equal and/or similar examples are all within the range of the invention and they are all consistent with the spirits of this invention, are all protected by our claims.

1. A kind of high voltage direct current broadband domain corona current measurement system, is characterized that, said system includes the sampling resistance sensor, the UHV local end measurement unit, the optical fiber transmission unit, the safe location measurement unit and the upper monitor, said sampling resistance sensor and UHV local end measurement unit both set in the integrated UHV local unit, said sampling resistance sensor samples the corona current signal of the HVDC line, and converts said corona current signal to the voltage signal, said UHV local end measurement unit collects said voltage signal, and gets the optical signal by photoelectric conversion, said optical signal transforms to said safe location measurement unit by said optical fiber transmission unit, said upper monitor performs processing the voltage signal, storage it and display it.

2. A kind of high voltage direct current broadband domain corona current measurement system according to claim 1, is characterized that, said integrated UHV local unit includes the grading ring A, the sampling resistance sensor, the optical fiber waterproof connector, the UHV local end measurement unit and the shielding ring; both sides of the integrated UHV local unit are respectively provided with the sampling resistance sensor and the UHV local end measurement unit, the outsides of said sampling resistance sensor and UHV local end measurement unit both provided with the shielding ring, the junction between said UHV local end measurement unit and its outside shielding ring has setting an optical fiber waterproof connector for leading the optical signal.

3. A kind of high voltage direct current broadband domain corona current measurement system according to claim 1, is characterized that, said sampling resistance sensor includes the shielding case, the epoxy resin insulating flange, the PE insulating framework, the compartments body and the sampling resistance, said sampling resistances have the same resistance value, are circumferentially arranged and use the parallel form; locating in the internal of the compartments body, said compartments body uses the PE insulating framework for being mechanical support bracket, the outside of the PE insulating framework provides the shielding case, the two ends of the said sampling resistance sensor links to the tubular bus-bar respectively by said epoxy resin insulating flange and the UHV local end measurement unit.

4. A kind of high voltage direct current broadband domain corona current measurement system according to claim 1, is characterized that, said UHV local end measurement unit includes the high speed broadband domain data acquisition unit, UBS port ,the photoelectric conversion unit A, the serial port, the energy comprehensive management unit and the independent power supply unit, the said high speed broadband domain data acquisition unit connects with said sampling resistance sensor, collects said voltage signals, said voltage signal is input onto said photoelectric conversion unit A through said USB port, after conversion gets said optical signal, the said energy comprehensive management unit links to the photoelectric conversion unit A via serial port ,said independent power supply unit supplies power to the high speed broadband domain data acquisition unit, the energy comprehensive management unit and the photoelectric conversion unit A.

5. A kind of high voltage direct current broadband domain corona current measurement system according to claim 4, is characterized that, said independent power supply unit includes storage battery, said storage battery includes battery protect board, said battery protect board uses LFP materials.

6. A kind of high voltage direct current broadband domain corona current measurement system according to claim 5, is characterized that, said storage battery includes optical fiber charging unit, using the optical fiber for optical signal charging said storage battery.

7. A kind of high voltage direct current broadband domain corona current measurement system according to claim 4, is characterized that, said high speed broadband domain data acquisition unit includes the AD convert unit, the FPGA unit, the ARM control unit, the buffer cell and the network transmission unit, wherein said FPGA unit uses the sampling clock to control said AD convert unit converting the corona current signal collected by the sampling resistance sensor into digital signal, and command the buffer cell A to cache the digital signal, said ARM control unit commands the FPGA unit and buffer cell B transfer the digital signal, said network transmission unit transfers the digital signal to the said photoelectric conversion unit A by the USB port.

8. A kind of high voltage direct current broadband domain corona current measurement system according to claim 4, is characterized that, said energy comprehensive management unit includes the power input interface, the power conversion unit, the power supply control circuit, the central control unit, the protection circuit, the power output interface A and the power output interface B, wherein said power conversion unit links to said independent power supply unit via said power input interface, supplying power for said central processing unit and the power supply control circuit ,which is the one hand to provide power for said central processing unit and the power supply control circuit ,on the other hand is controlling the power output interface A and the power output interface B to output different voltage respectively, said central control unit controls said protection circuit and the power supply control circuit, to realize the power output controlling through the circuit on-off of said power supply control circuit, said protection circuit includes the gas discharge tube and the corresponding parallel TVS with it, to make sure that said energy comprehensive management unit cannot be surged by the instantaneous high pressure.

9. A kind of high voltage direct current broadband domain corona current measurement system according to claim 1, is characterized that, said optical fiber transmission unit includes the optical fiber and the optical fiber insulator, said optical fiber uses the outdoor multimode optical cable, said optical fiber insulator transfers the said optical signal form the UHV local end measurement unit to said safe location measurement unit.

10. A kind of high voltage direct current broadband domain corona current measurement system according to claim 1, is characterized that, said safe location measurement unit includes the photoelectric conversion unit B, the USB port, the serial port and the power subsystem, wherein said USB port and serial port link to the photoelectric conversion unit respectively, said power subsystem supplies power for the photoelectric conversion unit B.

11. A kind of high voltage direct current broadband domain corona current measurement system according to claim 1, is characterized that, said upper monitor connects to the said safe location measurement unit by the USB port and the serial port, it receives, stores and processes the said voltage signal to get the corona current signal.

12. A kind of high voltage direct current broadband domain corona current measurement system according to claim 1, is characterized that, the sampling rate of said corona current signal is 1 kHz˜1 GHz, its sampling depth is 1 kB˜128 MB.
